(19) United States
(12) Patent Application Publication
(10) Pub. No.: US 2018/0138263 A1
(43) Pub. Date: May 17, 2018

(54) SEMICONDUCTOR STRUCTURE AND METHOD FOR FORMING THE SAME

(71) Applicant: UNITED MICROELECTRONICS CORP., Hsinchu (TW)

(72) Inventors: Ko-Wei Lin, Taichung City (TW); Yen-Chen Chen, Tainan City (TW); Chin-Fu Lin, Tainan City (TW); Chun-Yuan Wu, Yunlin County (TW); Chun-Ling Lin, Tainan City (TW)

(21) Appl. No.: 15/350,453

(22) Filed: Nov. 14, 2016

(51) Int. Cl. H01L 49/02

(52) U.S. Cl. CPC H01L 28/75

(57) ABSTRACT

A semiconductor structure includes a capacitor. The capacitor includes a bottom electrode, a first high-k dielectric layer, a second high-k dielectric layer and a top electrode. The bottom electrode includes a first layer and a second layer disposed on the first layer. The bottom electrode is formed of TiN. The first layer has a crystallization structure. The second layer has an amorphous structure. The first high-k dielectric layer is disposed on the bottom electrode. The first high-k dielectric layer is formed of TiO₂. The second high-k dielectric layer is disposed on the first high-k dielectric layer. The second high-k dielectric layer is formed of a material different from TiO₂. The top electrode is disposed on the second high-k dielectric layer.

### TECHNICAL FIELD

The disclosure relates to a semiconductor structure and a method for forming the same. More particularly, the disclosure relates to a semiconductor structure comprising a capacitor and a method for forming the same.

### BACKGROUND

Capacitors are widely used in electronic devices, such as IC devices. A capacitor may be constituted by two electrodes and a high-k dielectric layer disposed between the two electrodes. A high capacity value can be achieved by using a dielectric material having a higher dielectric constant. However, this approach is limited by the material characteristics. Increasing the areas of the electrodes may be useful, but conflict with the current of shrinking the sizes of IC devices. An alternative approach is decreasing the thickness of the high-k dielectric layer. However, this may be disadvantageous for maintaining the mechanical reliability of the structure.

### SUMMARY

This disclosure is directed to a semiconductor structure and a method for forming the same. The semiconductor structure comprises a capacitor having a high capacity value.

According to some embodiments, the semiconductor structure comprises a capacitor. The capacitor comprises a bottom electrode, a first high-k dielectric layer, a second high-k dielectric layer and a top electrode. The bottom electrode comprises a first layer and a second layer disposed on the first layer. The bottom electrode is formed of TiN. The first layer has a crystallization structure. The second layer has an amorphous structure. The first high-k dielectric layer is disposed on the bottom electrode. The first high-k dielectric layer is formed of TiO₂. The second high-k dielectric layer is disposed on the first high-k dielectric layer. The second high-k dielectric layer is formed of a material different from TiO₂. The top electrode is disposed on the second high-k dielectric layer.

According to some embodiments, the method comprises forming a capacitor. The formation of the capacitor comprises the following steps. First, a bottom electrode is formed. This step comprises forming a first layer of crystallized TiN and forming a second layer of amorphous TiN. The first layer is formed by deposition with a first N₂ flow rate. The second layer is formed on the first layer by deposition with a second N₂ flow rate lower than the first N₂ flow rate, such that a lattice mismatch exists between the first layer and the second layer. Thereafter, a first high-k dielectric layer of TiO₂ is formed on the bottom electrode by oxidizing the second layer.

### BRIEF DESCRIPTION OF THE DRAWINGS

FIG. 1 illustrates a semiconductor structure according to embodiments.

FIG. 2 illustrates the sequence of some steps of a method for forming a semiconductor structure according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. For clarity, some elements may be omitted from the figures, and the elements in the figures may not reflect their real sizes and configurations. It is contemplated that elements and features of one embodiment may be beneficially incorporated into another embodiment without further recitation.

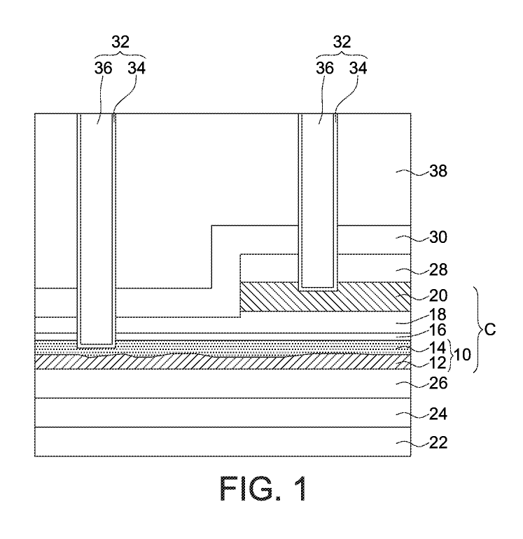

Referring to FIG. 1, a semiconductor structure according to embodiments is shown. The semiconductor structure comprises a capacitor C. The capacitor C comprises a bottom electrode 10, a first high-k dielectric layer 16, a second high-k dielectric layer 18 and a top electrode 20.

The bottom electrode 10 comprises a first layer 12 and a second layer 14 disposed on the first layer 12. The bottom electrode 10 is formed of TiN. The first layer 12 has a crystallization structure. The second layer 14 has an amorphous structure. As such, a lattice mismatch exists between the first layer 12 and the second layer 14. The lattice mismatch can lead to a reduction of the leakage current, which is advantageous for the capacitor C. According to some embodiments, the first layer 12 may be in a N-rich poison mode, and the crystallization structure has a column configuration. The second layer 14 may be in a Ti-rich metallic mode. In some embodiments, the bottom electrode 10 has a thickness from about 100 Å to about 2000 Å.

The first high-k dielectric layer 16 is disposed on the bottom electrode 10. The first high-k dielectric layer 16 is formed of TiO₂. TiO₂ is a material having a dielectric constant even higher than other typical materials used for a high-k dielectric layer. According to some embodiments, the first high-k dielectric layer 16 has a thickness smaller than 50 Å.

The second high-k dielectric layer 18 is disposed on the first high-k dielectric layer 16. The second high-k dielectric layer 18 is formed of a material different from TiO₂. According to some embodiments, the second high-k dielectric layer 18 may be formed of at least one of HfO₂, Al₂O₃, Ta₂O₃, ZrO₂ and the like. In the capacitor C, because the first high-k dielectric layer 16 of TiO₂ is formed, the second high-k dielectric layer 18 may have an increased thickness without degrade the total capacity value of the capacitor C. Thereby, the second high-k dielectric layer 18 can provide an improved mechanical reliability. However, according to some embodiments, the second high-k dielectric layer 18 has a thickness equal to or smaller than 200 Å. In some embodiments, as shown in FIG. 1, the second high-k dielectric layer 18 may have a stepped configuration.

The top electrode 20 is disposed on the second high-k dielectric layer 18. According to some embodiments, the top electrode 20 may be formed of at least one of TiN, Al and the like. In some embodiments, the top electrode 20 has a thickness of about 100 Å to about 2000 Å.

In some embodiments, the capacitor C is formed on a substrate 22 of the semiconductor structure. According to some embodiments, the semiconductor structure may further comprise one or more buffer layers disposed on the substrate 22, and the capacitor C is disposed on the one or more buffer layers. In some embodiments, the one or more buffer layers comprise a first buffer layer 24 and a second buffer layer 26. For example, the first buffer layer 24 may be formed of SiCN and has a thickness of about 750 Å. For example, the second buffer layer 26 may be formed of oxide, such as plasma-enhanced oxide, and has a thickness of about 1000 Å.

According to some embodiments, the semiconductor structure may further comprise one or more dielectric layers disposed on the capacitor C. In some embodiments, the one or more dielectric layers comprise a first dielectric layer 28 and a second dielectric layer 30. For example, the first dielectric layer 28 may be formed of SiON and has a thickness of about 400 Å. For example, the second dielectric layer 30 may be formed of SiN and has a thickness of about 1200 Å.

According to some embodiments, the semiconductor structure may further comprise contacts 32 connected to the bottom electrode 10 and the top electrode 20, respectively. The contacts 32 may, for example, penetrate through an interlayer dielectric 38. In some embodiments, each contact 32 may comprise a barrier layer 34 and conductive material 36.

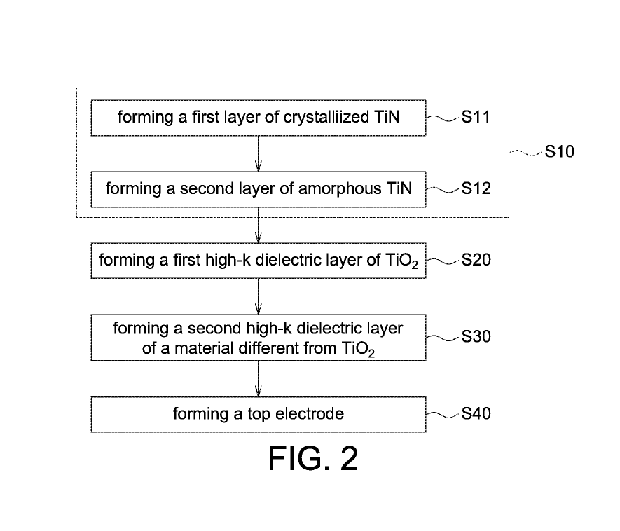

Now the description is directed to a method for forming such a semiconductor structure. In particular, the method comprises forming the capacitor C. The flow sequence of forming the capacitor C is shown in FIG. 2.

In the first step S10 of the formation of the capacitor C, a bottom electrode 10 is formed. The step S10 may comprise a first step S11 and a second step S12. In the step S11, a first layer 12 of crystallized TiN is formed. The first layer 12 may be formed by deposition with a first N₂ flow rate. In the step S12, a second layer 14 of amorphous TiN is formed. The second layer 14 is formed on the first layer 12. The second layer 14 may be formed by deposition with a second N₂ flow rate lower than the first N₂ flow rate, such that a lattice mismatch exists between the first layer 12 and the second layer 14. For example, the first N₂ flow rate may be equal to or higher than 70 sccm, and the second N₂ flow rate may be equal to or lower than 40 sccm. According to some embodiments, the first layer 12 and the second layer 14 may be formed by physical chemical deposition. In some embodiments, the first layer 12 and the second layer 14 are formed in-situ.

In the next step S20 of the formation of the capacitor C, a first high-k dielectric layer 16 of TiO₂ is formed. The first high-k dielectric layer 16 is formed on the bottom electrode 10. The first high-k dielectric layer 16 is formed by oxidizing the second layer 14, which may be a Ti-rich metallic mode as described above. According to some embodiments, the second layer 14 may be oxidized by providing O₃ and H₂O vapor. In some embodiments, the O₃ and H₂O vapor are provided in a pretreatment process for a next step 30, in which a second high-k dielectric layer 18 is formed on the first high-k dielectric layer 16. In such embodiments, the first high-k dielectric layer 16 is formed by an ordinary process, and thereby an additional process is unneeded.

The formation of the capacitor C may further comprise a step S30, in which a second high-k dielectric layer 18 of a material different from TiO₂ is formed. For example, HfO₂, Al₂O₃, Ta₂O₃, ZrO₂ or the like may be used to form the second high-k dielectric layer 18. The second high-k dielectric layer 18 is formed on the first high-k dielectric layer 16.

The formation of the capacitor C may further comprise a step S40, in which a top electrode 20 is formed. The top electrode 20 is formed on the second high-k dielectric layer 18. The top electrode 20 may be formed of TiN, Al or the like.

It is contemplated that the method for forming the semiconductor structure according to the embodiments may comprise other steps. For example, one or more buffer layers, such as the first buffer layer 24 and the second buffer layer 26, may be formed before the formation of the capacitor C. For example, one or more dielectric layers, such as the first dielectric layer 28 and the second dielectric layer 30, may be formed on the capacitor C. For example, contacts 32 may be formed connected to the bottom electrode 10 and the top electrode 20, respectively.

According to the embodiments as described above, the capacitor C of the semiconductor structure can provide a high capacity value through the disposition of the first high-k dielectric layer 16 formed of TiO₂. At the same time, the mechanical reliability can be improved due to the disposition of the second high-k dielectric layer 18 having an increased thickness. In addition, since a lattice mismatch exists in the bottom electrode 10 of the capacitor C, the leakage current can be reduced.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor structure, comprising:
a capacitor comprising:
a bottom electrode comprising a first layer and a second layer disposed on the first layer, the bottom electrode formed of TiN, wherein the first layer has a crystallization structure formed by a deposition with a first N₂ flow rate, the second layer has an amorphous structure formed by a deposition with a second N₂ flow rate, and the second N₂ flow rate is lower than the first N₂ flow rate;
a first high-k dielectric layer disposed on the bottom electrode, the first high-k dielectric layer formed of TiO₂;
a second high-k dielectric layer disposed on the first high-k dielectric layer, the second high-k dielectric layer formed of a material different from TiO₂; and
a top electrode disposed on the second high-k dielectric layer.

2. The semiconductor structure according to claim 1, wherein the first layer is in a N-rich poison mode, the crystallization structure has a column configuration, and the second layer is in a Ti-rich metallic mode.

3. The semiconductor structure according to claim 1, wherein the bottom electrode has a thickness from 100 Å to 2000 Å.

4. The semiconductor structure according to claim 1, wherein the first high-k dielectric layer has a thickness smaller than 50 Å.

5. The semiconductor structure according to claim 1, wherein the second high-k dielectric layer is formed of at least one of HfO₂, Al₂O₃, Ta₂O₃ and ZrO₂.

6. The semiconductor structure according to claim 1, wherein the second high-k dielectric layer has a thickness equal to or smaller than 200 Å.

7. The semiconductor structure according to claim 1, wherein the top electrode is formed of at least one of TiN and Al.

8. The semiconductor structure according to claim 1, wherein the top electrode has a thickness of 100 Å to 2000 Å.

9. The semiconductor structure according to claim 1, further comprising:
one or more buffer layers, wherein the capacitor is disposed on the one or more buffer layers.

10. The semiconductor structure according to claim 1, further comprising:
one or more dielectric layers disposed on the capacitor.

11. The semiconductor structure according to claim 1, further comprising:
contacts connected to the bottom electrode and the top electrode, respectively.

12. A method for forming a semiconductor structure, comprising:
forming a capacitor comprising:
forming a bottom electrode comprising:
forming a first layer of crystallized TiN by deposition with a first N₂ flow rate; and
forming a second layer of amorphous TiN on the first layer by deposition with a second N₂ flow rate lower than the first N₂ flow rate, such that a lattice mismatch exists between the first layer and the second layer; and
forming a first high-k dielectric layer of TiO₂ on the bottom electrode by oxidizing the second layer.

13. The method according to claim 12, wherein the first N₂ flow rate is equal to or higher than 70 sccm, and the second N₂ flow rate is equal to or lower than 40 sccm.

14. The method according to claim 12, wherein the first layer and the second layer are formed in-situ.

15. The method according to claim 12, wherein the first layer and the second layer are formed by physical chemical deposition.

16. The method according to claim 12, wherein the second layer is oxidized by providing O₃ and H₂O vapor.

17. The method according to claim 16, wherein the O₃ and H₂O vapor are provided in a pretreatment process for forming a second high-k dielectric layer on the first high-k dielectric layer.

18. The method according to claim 12, wherein forming the capacitor further comprising:
forming a second high-k dielectric layer of a material different from TiO₂ on the first high-k dielectric layer.

19. The method according to claim 18, wherein forming the capacitor further comprising:
forming a top electrode on the second high-k dielectric layer.
